(19) United States
(12) Patent Application Publication
(10) Pub. No.: US 2014/0110671 A1
(43) Pub. Date: Apr. 24, 2014

(54) LIGHT SOURCE MODULE AND ILLUMINATION DEVICE INCLUDING A THERMOELECTRIC DEVICE

(71) Applicant: SAMSUNG ELECTRONICS CO., LTD., Suwon-si (KR)

(72) Inventor: Jung Hoon KIM, Hwaseong (KR)

(21) Appl. No.: 13/926,975

(22) Filed: Jun. 25, 2013

(30) Foreign Application Priority Data
Oct. 24, 2012 (KR) 10-2012-0118696

(51) Int. Cl. H01L 33/64

(52) U.S. Cl. CPC H01L 33/645; Y10S 977/833; B82Y 99/00
USPC 257/29; 977/833

(57) ABSTRACT

A light source module includes at least one light emitting device and a thermoelectric device coupled to the at least one light emitting device. The thermoelectric devices includes a plurality of conductive layers, made of a resin material containing a thermoelectric conversion material, and a plurality of insulating layers laminated to the conductive layers. The thermoelectric device generates electricity by using heat from the light emitting device.

### CROSS-REFERENCE TO RELATED APPLICATIONS

This application claims the priority of Korean Patent Application No. 10-2012-0118696 filed on Oct. 24, 2012, in the Korean Intellectual Property Office, the disclosure of which is incorporated herein by reference.

### TECHNICAL FIELD

The present disclosure relates to a light source module and an illumination device including a thermoelectric device.

### BACKGROUND

LED illumination devices, consuming relatively low amounts of power and having relatively long lifespans, are classified as environmentally-friendly products. However, energy consumed due to heat is still too high, and thus, technical efforts aimed at improving this problem are constantly being undertaken.

### SUMMARY

An aspect of the present disclosure provides a light source module having enhanced energy usage efficiency and an illumination device including the same.

According to an aspect of the present disclosure, there is provided a light source module including: at least one light emitting device; and a thermoelectric device coupled to the at least one light emitting device and comprising a plurality of conductive layers, made of a resin material containing a thermoelectric conversion material, and a plurality of insulating layers laminated to the conductive layers, the thermoelectric device generating electricity by using heat from the light emitting device.

The thermoelectric conversion material may include carbon nanotubes (CNT), and the resin material may be an organic substance.

The thermoelectric device may include a first conductive layer including n-type CNT, a second conductive layer including p-type CNT, and an insulating layer in contact with and interposed between the first conductive layer and the second conductive layer.

The thermoelectric device may be a film having a multilayer structure which includes alternately laminated conductive layers and insulating layers such that each insulating layer is interposed between a pair of conductive layers, and such that each insulating layer contacts a conductive layer including n-type CNT on one side thereof and contacts a conductive layer including p-type CNT on an other side thereof.

The first conductive layer and the second conductive layer may be made of a resin material comprising n-type CNT and p-type CNT respectively, and the first conductive layer and the second conductive layer are thin films.

The first conductive layer and the second conductive layer may contact each other to form a junction at one end of the insulating layer.

Conductive layers disposed on opposite sides of an insulating layer may contact each other to form a junction at one end of the insulating layer, and junctions may be formed at alternating ends of the laminated conductive layers in the lamination direction to connect the conductive layers in a zigzag pattern.

The thermoelectric device may have ductility so as to be bent or folded.

The light source module may further include a housing accommodating and supporting the thermoelectric device therein.

According to another aspect of the present disclosure, there is provided an illumination device including: a body having an opening; a light source installed within the body and emitting light outwardly through the opening; and a thermoelectric device installed within the body and comprising a plurality of conductive layers, made of a resin material containing carbon nanotubes (CNT), and a plurality of insulating layers laminated to the conductive layers, the thermoelectric device generating electricity by using a temperature difference between the body and the light source.

The thermoelectric device may include a first conductive layer including n-type CNT, a second conductive layer including p-type CNT, and an insulating layer in contact with and interposed between the first and second conductive layers.

The thermoelectric device may be disposed between the body and the light source such that one end thereof is connected to the main body and the other end thereof is connected to the light source.

The body may be heated or cooled according to an external environment to form a temperature difference relative to the light source.

The illumination device may further include an electric condenser, coupled to the thermoelectric device, for storing (or charging) electricity generated by the thermoelectric device and providing the stored (or charged) electricity to the light source.

The illumination device may further include a cover installed in the body and covering the light source.

According to another aspect of the present disclosure, there is provided a light source module including a light emitting device and a thermoelectric device coupled to the light emitting device. The thermoelectric device includes a plurality of conductive layers and a plurality of insulating layers laminated to the conductive layers, the thermoelectric device generating electricity by using heat from the light emitting device. The thermoelectric device is a multilayer structure formed by laminating together alternating conductive layers and insulating layers such that each insulating layer is interposed between a pair of conductive layers, and the conductive layers disposed on opposite sides of an insulating layer contact each other to form a junction at one end of the insulating layer.

The junctions between conductive layers formed at ends of the insulating layers may be formed at alternating ends of the conductive layers in the multilayer structure.

The conductive layers in the multilayer structure may alternately include a thermoelectric conversion material including n-type carbon nanotubes (CNTs) and a thermoelectric conversion material including p-type CNTs, such that each junction is formed between a thermoelectric conversion material including n-type CNTs and a thermoelectric conversion material including p-type CNTs.

The thermoelectric device can be coupled to the light emitting device by one end surface of the thermoelectric device that contacts a plurality of the conductive layers and a plurality of the insulating layers of the multilayer structure.

The foregoing technical solutions do not fully enumerate all of the features of the present disclosure. The foregoing and other objects, features, aspects and advantages of the present disclosure will become more apparent from the following detailed description when taken in conjunction with the accompanying drawings.

### BRIEF DESCRIPTION OF THE DRAWINGS

The above and other aspects, features and other advantages of the present disclosure will be more clearly understood from the following detailed description taken in conjunction with the accompanying drawings, in which:

FIGS. 1A and 1B are a perspective view and a cross-sectional view schematically showing a light source module according to an embodiment of the present disclosure;

FIGS. 2A and 2B are a perspective view and a cross-sectional view schematically showing a light source module according to another embodiment of the present disclosure;

FIGS. 3A and 3B are cross-sectional views schematically showing various light source modules according to other embodiments of the present disclosure;

FIG. 4 is an exploded perspective view schematically illustrating a thermoelectric device according to an embodiment of the present disclosure;

FIG. 5 is a cross-sectional view of the thermoelectric device according to an embodiment of the present disclosure;

FIG. 6 is a cross-sectional view schematically illustrating as thermoelectric device in which a plurality of layers are laminated together;

FIG. 7 is a cross-sectional view schematically showing a structure in which a thermoelectric device is bent to be disposed between a high temperature element and a low temperature element;

FIGS. 8A, 8B, 8C, and 8D are cross-sectional views schematically illustrating thermoelectric devices bent to have various shapes;

FIG. 9 is a cross-sectional view schematically illustrating an illumination device according to an embodiment of the present disclosure;

FIG. 10 is a cross-sectional view schematically illustrating an operational state of the illumination device of FIG. 9;

FIG. 11 is a view schematically illustrating an illumination device according to another embodiment of the present disclosure;

FIG. 12 is a cross-sectional view of the illumination device of FIG. 11; and

FIGS. 13A and 13B are views schematically illustrating operational states of the illumination device of FIG. 12 in the daytime and nighttime.

### DETAILED DESCRIPTION

Embodiments of the present disclosure will now be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the teachings to those skilled in the art. In the drawings, the shapes and dimensions of elements may be exaggerated for clarity, and the same reference numerals will be used throughout to designate the same or like components.

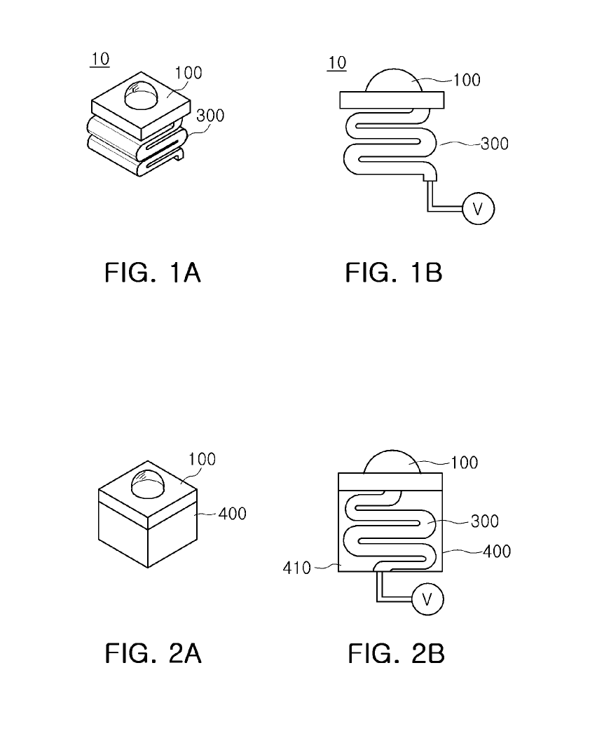

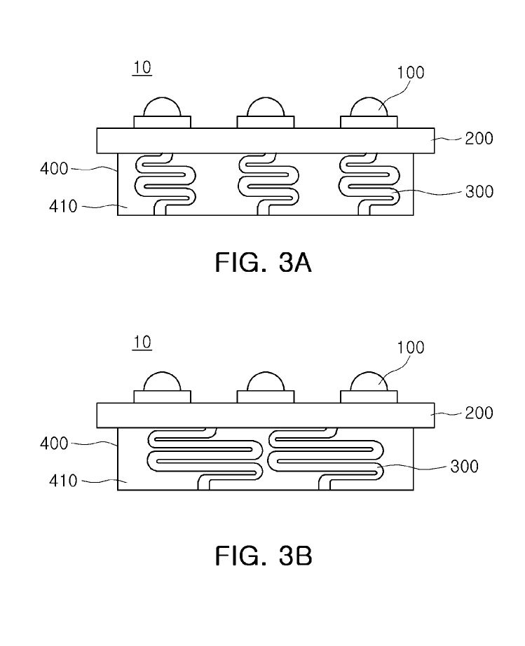

FIGS. 1A, 1B, 2A, 2B, 3A, and 3B illustrate a light source module according to one embodiment and illustrate modifications thereof. FIGS. 1A and 1B are a perspective view and a cross-sectional view schematically showing a light source module according to one embodiment. FIGS. 2A and 2B are a perspective view and a cross-sectional view schematically showing a light source module according to another embodiment. FIGS. 3A and 3B are cross-sectional views schematically showing various light source modules according to other embodiments.

Referring to FIGS. 1A, 1B, 2A and 2B, a light source module 10 may include at least one light emitting device 100 and a thermoelectric device 300 connected to the light emitting device 100.

The light emitting device 100 generally is a type of semiconductor device generating and emitting light having a predetermined wavelength upon receiving power applied thereto from an outside source. The light emitting device 100 may include a light emitting diode (LED). The light emitting device 100 may emit blue light, green light, or red light according to a material contained therein, and may also emit white light.

In FIGS. 1A, 1B, 2A, and 2B, the light emitting device 100 is illustratively shown as a single package unit including an LED chip therein, but the present disclosure is not limited thereto and various other types of light emitting devices may be employed. For example, the light emitting device 100 may be a chip itself.

As illustrated in FIGS. 3A and 3B, a plurality of light emitting devices 100 may be arranged on a board 200. In this case, each of the light emitting devices 100 may be of a same type of light emitting device for generating light having the same wavelength. Alternatively, the light emitting devices 100 may be of various types of light emitting devices, and/or may generate light beams having different wavelengths. Meanwhile, in cases in which the light emitting device 100 illustrated in FIGS. 1A, 1B, 2A, and 2B is a chip, the light emitting device 100 may be supportedly disposed or mounted on a board 200 (not shown in FIG. 1A, 1B, 2A, or 2B).

The board 200 allows the light emitting device 100 to be disposed or mounted on one surface thereof and provides support to the light emitting device 100. The board 200 may be made of a material having excellent thermal conductivity and serve as a heat sink. For example, the board 200 may be made of a metal or include a metal compound as a material thereof, and may include a metal-core printed circuit board (MCPCB). Also, without being limited thereto, the board 200 may be a general FR4 PCB and may be made of an organic resin material containing epoxy, triazine, silicon, polyimide, or the like, and any other organic resin materials, or may be made of a ceramic material such as AlN, Al₂O₃, or the like.

As illustrated in FIGS. 1A, 1B, 2A, and 2B, the thermoelectric device 300 may be directly connected to the light emitting device 100. The thermoelectric device 300 may generate electricity by using heat generated by the light emitting device 100. Also, as illustrated in FIGS. 2A and 2B, the thermoelectric device 300 may be accommodated in a housing 400 provided on a rear side of the light emitting device 100 so as to be supported and protected. In this case, an internal space 410 within the housing may be in a vacuum state or may be filled with a material having low thermal conductivity.

Hereinafter, the structure in which the thermoelectric device 300 is accommodated in the housing 400 will be described as a basic structure. However, the present disclosure is not limited thereto.

As illustrated in FIGS. 3A and 3B, in examples in which the light emitting device 100 is disposed on one surface of a board 200, the thermoelectric device 300 may be provided on the other/opposite surface of the board 200. The thermoelectric device generates electricity by using heat generated from the light emitting device 100. In the example shown in FIGS. 3A and 3B, a plurality of thermoelectric devices 300 may be provided. As shown in FIG. 3A, the number of thermoelectric devices 100 can correspond to the number of light emitting devices 100. Alternatively, a single thermoelectric device 300 may be provided irrespective of the number of the light emitting devices 100, or various other numbers of thermoelectric devices 300 may be provided (see, e.g., FIG. 3B).

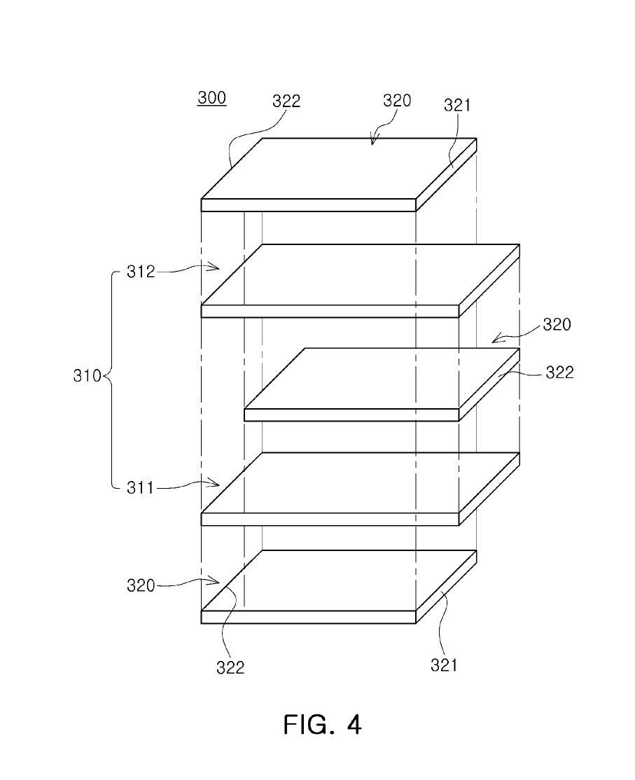

The thermoelectric device 300 may have ductility enabling the device to be warped or bent so as to have various shapes. Hereinafter, the thermoelectric device 300 according to an embodiment of the present disclosure will be described in detail. FIGS. 4 through 8 schematically illustrate the thermoelectric device 300.

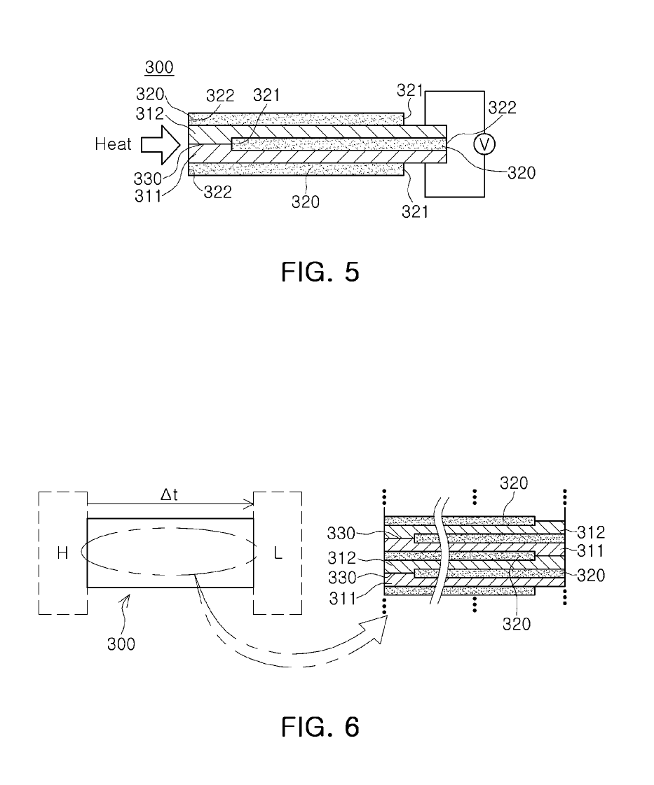

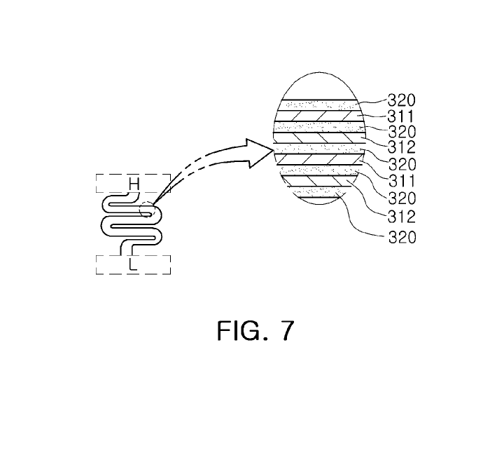

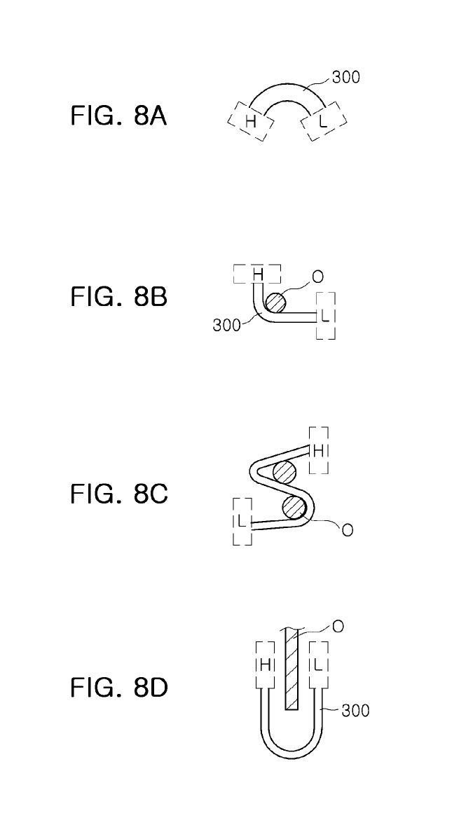

FIG. 4 is an exploded perspective view schematically illustrating a thermoelectric device 300 according to an embodiment of the present disclosure. FIG. 5 is a cross-sectional view of the thermoelectric device 300 according to an embodiment of the present disclosure. FIG. 6 is a cross-sectional view schematically illustrating a state in which thermoelectric devices 300 of FIG. 5 are laminated as a plurality of layers. FIG. 7 is a cross-sectional view schematically showing a structure in which the thermoelectric device 300 is bent to be disposed between a high temperature element and a low temperature element. FIG. 8 is a cross-sectional view schematically illustrating thermoelectric devices 300 bent to have various shapes.

As illustrated in FIGS. 4 through 6, the thermoelectric device 300 may have a film structure in which a conductive layer 310 and an insulating layer 320 are alternately laminated. The conductive layer may be of a resin material, such as an organic substance, and may contain a thermoelectric transformation material.

In this case, an organic resin such as an epoxy resin may be included as the resin material, and carbon nanotubes (CNT) may be included as the thermoelectric transformation material. Thus, the thermoelectric device 300 made of a resin material containing CNT may be an organic thermoelectric device that may be bent or warped to have various shapes. Unlike other thermoelectric devices formed of inorganic materials, the thermoelectric device 300 has a single film structure in which the conductive layers 310 and the insulating layers 320 are laminated. The thermoelectric device 300 has ductility, such that the thermoelectric device 300 may be folded to have a multilayer shape as illustrated in FIGS. 1A, 1B, 2A, 2B, 3A, and 3B.

The thermoelectric device 300 may include a first conductive layer 311, a second conductive layer 312, and the insulating layer 320.

The first conductive layer 311 and the second conductive layer 312 may include an n-type semiconductor layer and a p-type semiconductor layer, respectively, and may be formed as flexible thin films. In detail, the first conductive layer 311 and the second conductive layer 312 may include CNT films, such as thin films with CNT contained in a resin material having ductility.

CNT contained in the first conductive layer 311 and CNT contained in the second conductive layer 312 may have different electrical characteristics. For example, CNT contained in the first conductive layer 311 may be n-type CNT and CNT contained in the second conductive layer 312 may be p-type CNT, respectively. Thus, the first conductive layer 311 and the second conductive layer 312 may have different electrical characteristics.

The first conductive layer 311 and the second conductive layer 312 may be formed as flat thin films having shapes corresponding to each other, and may have a thickness ranging from, for example, 25 μm to 40 μm. In the present embodiment, the conductive layers 310 are illustrated as having a rectangular or other quadrangular shape, but the present disclosure is not limited thereto. The conductive layer 310 may be modified to have various structures to meet design requirements for a device in which the thermoelectric device 300 according to an embodiment of the present disclosure is installed.

The first conductive layer 311 and the second conductive layer 312 may be alternately laminated with the insulating layer 320 (to be described hereinafter) interposed therebetween to form a multilayer structure. Namely, a plurality of first conductive layers 311 and a plurality of second conductive layers 312 are alternately laminated with the insulating layer 320 interposed therebetween, respectively. Thus, since the insulating layers 320 are interposed between the first conductive layers 311 and the second conductive layers 312, respectively, the first conductive layers 311 and the second conductive layers 312 may be physically separated by the insulating layers 320. As such, the thermoelectric device 300 may have a stacked structure in which every other layer is an insulating layer 320. Either a first conductive layer 311 or a second conductive layer 312 is disposed between the insulating layers 320 of the stack. The first and second conductive layers 311 and 312 are disposed in alternation in the stack, such that one side of each insulating layer 320 contacts a first conductive layer 311 while an other/opposite side of the insulating layer 320 contacts a second conductive layer 312.

The insulting layers 320 may also be provided on the outermost surfaces of the first conductive layer 311 and the second conductive layer 312, respectively. Namely, the insulating layers 320 may be provided on an upper surface and a lower surface of the thermoelectric device 300 having the structure including the laminated conductive layers 310 and the insulating layers 320, respectively, to protect the conductive layer 310.

Each insulating layer 320 (with the exception of the insulating layers 320 disposed on the upper surface and lower surface of the thermoelectric device 300) is interposed between a first conductive layer 311 and a second conductive layer 312, and separates the first conductive layer 311 and the second conductive layer 312 by a distance corresponding to a thickness of the insulating layer 320. The first conductive layer 311 and the second conductive layer 312 are further electrically insulated from each other by the insulating layer 320. The insulating layer 320 may include a polyvinylidene difluoride (PVDF) film.

Each insulating layer 320 may have a flat thin film structure having a shape corresponding to that of the conductive layer(s) 310, and may have a size smaller than that of the conductive layer(s) 310. Thus, in a case in which the first conductive layer 311 and the second conductive layer 312 are attached to opposite sides or surfaces of an insulating layer 320 so as to be laminated to each other (or in a case in which insulating layers are attached to both surfaces of the first conductive layer and the second conductive layer so as to be laminated), end portions of the first and/or second conductive layers 311 and 312 may be exposed. In particular, the insulating layer 320 may only cover and contact one portion of a surface of a first or second conductive layer 311/312, leaving an end portion (or other portion) of the surface of the first or second conductive layer 311/312 exposed.

In detail, one end 321 of each insulating layer 320 may be disposed on an inner portion of the first conductive layer 311 and the second conductive layer 312, as shown in FIGS. 4-6. The inner portion may be a portion of the conductive layer that it spaced away from ends of the conductive layer. An other end 322 of the insulating layer 320 that is opposite to the one end 321 may be disposed so as to be coplanar with an end of the conductive layer. In this manner, the insulating layers 320 and the first and second conductive layers 311 and 312 may be laminated in a stack in which a portion of a surface of each conductive layer 311/312 in the stack is exposed (and does not contact an insulating layer 320), while the remainder of the surface of the conductive layer 311/312 is in contact with the insulating layer 320. In this case, the insulating layers 320 may be disposed and laminated in a zigzag manner (i.e., so as to be offset laterally relative to positions of other insulating layers 320 in the stack). As such, the other ends 322 of the insulating layers 320 can be coplanar with the alternating ends of the first and second conductive layers 311 and 312.

Meanwhile, the first conductive layer 311 and the second conductive layer 312 may be joined 330 at one end 321 of the insulating layer 320 so as to be electrically connected to each other. In detail, since one end 321 of the insulating layer 320 is disposed on an inner portion of the first and second conductive layers 311 and 312, the first conductive layer 311 and the second conductive layer 312 extend past the end 321 of the insulating layer 320 and may be joined (starting from one end 321 of the insulating layer 320) without the insulating layer 320 therebetween. Here, the joining 330 of the first and second conductive layers 311 and 312 may form a pn junction.

As illustrated, the junctions 330 are formed between adjacent first and second conductive layers 311 and 312, over the area of contact of the layers. The junctions 330 may be formed at alternating ends of the laminated first conductive layer 311 and the second conductive layer 312, along the lamination direction to connect the first conductive layer 311 and the second conductive layer 312 in a zigzag manner. Thus, a closed circuit in which the plurality of first conductive layers 311 and the plurality of second conductive layers 312 are connected in series may be formed.

As illustrated in FIG. 6, the thermoelectric device 300 may include a stack of tens or hundreds of layers laminated together, including the first conductive layers 311, the insulating layers 320, and the second conductive layer 312. Also, more than hundreds of layers may be laminated according to a requested generation amount.

The thermoelectric device 300 may be disposed between a high temperature element H and a low temperature element L. The high temperature element H may be an element having a temperature higher than that of the low temperature element L. The high temperature element H and the low temperature element L may be portions of elements constituting a device in which the thermoelectric device 300 is installed. For example, the high temperature element H may include the light emitting device 100 generating heat.

When there is a temperature gradient or difference Δt in a direction parallel to the surface of the conductive layers 311 and 312 (e.g., a temperature gradient or difference between the high temperature element H and the low temperature element L), electrons and holes move from the high temperature element H toward the low temperature element L due to the Seebeck effect and thereby change the temperature difference into a voltage. Namely, a potential difference (thermoelectromotive force) is generated so a current flows in the circuit formed by the first and second conductive layers 311 and 312. Thus, the thermoelectric device 300 may generate electricity by using heat generated by the light emitting device 100.

Generative capacity of the thermoelectric device 300 is generally proportional to the area of the thermoelectric device connecting the high temperature element H and the low temperature element L. Namely, as the area of the thermoelectric device 300 is increased, the generative capacity thereof is increased.

As illustrated in FIG. 7, the thermoelectric device 300 is folded in the form of multiple layers between the high temperature element H and the low temperature element L. The multi-layer structure increases the effective area of the thermoelectric device 300, and thereby increases the generative capacity of the thermoelectric device 300. The thermoelectric device 300 can be formed with a material having ductility as a type of organic thermoelectric device. The area of the thermoelectric device 300 may be increased by using a material have ductility as compared to a structure that is stiff and that is implemented only in linear form (e.g., like inorganic thermoelectric devices).

Upon confirming the electricity generation effect of the foregoing thermoelectric device 300, testing was performed as in the embodiments below.

In a first embodiment, a conductive layer formed of 72 layers was tested and a maximum generative capacity of 137 nW was measured at a temperature difference of 50° C. and using an area of 500 cm². Arithmetically, a theoretical maximum electricity generation amount of a thermoelectric device configured as a conductive layer (having an area of 500 cm²) formed of 300 layers exposed to a temperature difference of 100° C. is a maximum of 5 μW. Thus, when the area of the conductive layer is assumed to be 50 cm×30 cm, an electricity generation amount chargeable per day may be a maximum of 360 μW.

In particular, the price of electricity produced through the thermoelectric device having a CNT film/PVDF film layered structure according to the present embodiment was calculated to be approximately 1 dollar per Watt, which is equivalent to nearly one-seventh ( 1/7) of the price of generating electricity through an existing thermoelectric device made of an inorganic material such as Bi₂Te₃, confirming that the thermoelectric device according to the present embodiment is excellent in terms of economical efficiency.

As illustrated in FIGS. 8A, 8B, 8C, and 8D, the thermoelectric device 300 made of a resin material having ductility may be warped or bent to have various shapes. In situations in which one or more obstacles O exist the obstacles can cause difficulty in installing a thermoelectric device 300, notably when the obstacles are in locations in which the thermoelectric device 300 is to be installed. In such situations, the thermoelectric device 300 having ductility may be warped or bent to bypass the obstacle(s), thereby increasing the degree of freedom in design.

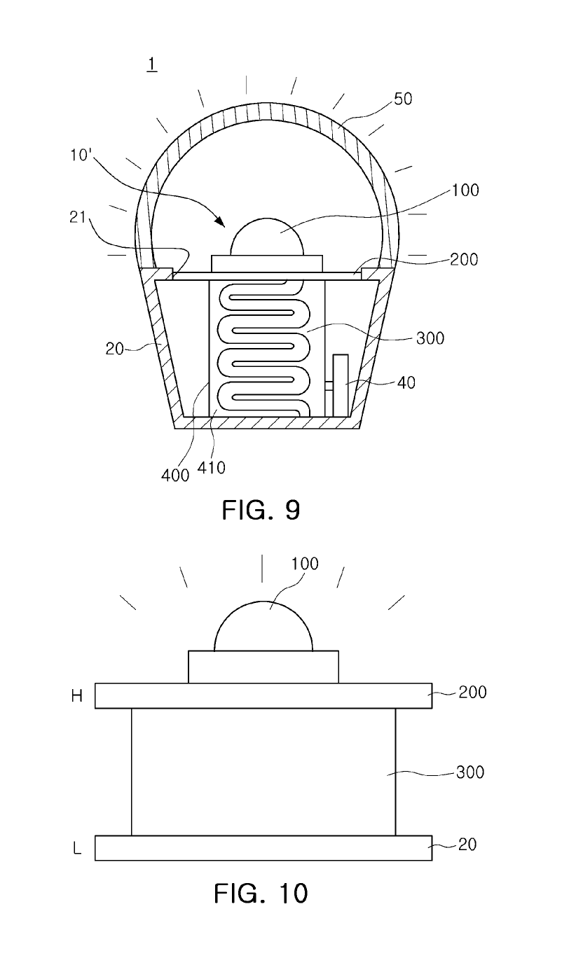

An illumination device according to an embodiment of the present disclosure will be described with reference to FIGS. 9 and 10. FIG. 9 is a cross-sectional view schematically illustrating an illumination device according to an embodiment of the present disclosure. FIG. 10 is a cross-sectional view schematically illustrating an operational state of the illumination device.

An illumination device 1 according to the present embodiment may be used as, for example, a bulb lamp. In detail, referring to FIGS. 9 and 10, the illumination device may include a body 20, a light source 10′, and the thermoelectric device 300, and may further include an electric condenser 40.

The body 20 has an accommodation space having a predetermined size, and the light source 10′, the thermoelectric device 300, the electric condenser 40, or the like, may be installed in the accommodation space of the body 20. An opening 21 is formed in the body 20 to allow the light source 10′ to be installed therein, and light generated by the light source 10′ may be emitted and irradiated outwardly.

The light source 10′ may include at least one light emitting device 100 and the board 200 allowing the light emitting device 100 to be disposed or mounted thereon and electrically connecting it. The structure of the light emitting device 100 and the board 200 is substantially the same as that of the light emitting device 100 and the board 200 of the light source module 10. Thus, a detailed description of the light emitting device 100 and the board 200 will be omitted.

The thermoelectric device 300 may be installed within the body 20 and generate electricity by using a temperature difference between the body 20 and the light source 10′. A specific structure of the thermoelectric device 300 is illustrated in FIGS. 4 through 8. Since the thermoelectric device 300 has been described in detail with reference to FIGS. 4 through 8, the detailed description thereof will be omitted.

In the case of the illumination device 1 according to the present embodiment, the thermoelectric device 300 is disposed between the body 20 and the light source 10′ such that one end thereof is connected to the body 20 and the other end thereof is connected to the light source 10′. In this case, the light source 10′ and the body 20 may be a high temperature element H and a low temperature element L, respectively. For example, in case in that the light source 10′ corresponds to a high temperature element H, the body 20 may correspond to a low temperature element L.

In detail, as illustrated in FIG. 10, when the illumination device 1 is driven or powered, the light emitting device 100 emits heat together with light. Thus, the light source 10′ generating thermal energy according to light emission of the light emitting device 100 is a high temperature element H and the body 20 exposed to the ambient environment (in the atmosphere) has a relatively low temperature, being a low temperature element L. A temperature gradient or difference may thus be generated between the low temperature element L and the high temperature element H.

Referring to an actually measured temperature values of the bulb lamp as illustrated in FIG. 9, in a case in which an atmosphere temperature is 25° C., a temperature of the light emitting device 100 was measured to be approximately 82.4° C., and a temperature difference ranging from about 50° C. to 100° C. is generated, although there may be a difference among products. Through such a temperature difference, electricity may be generated and the generated electricity may be charged in the electric condenser 40.

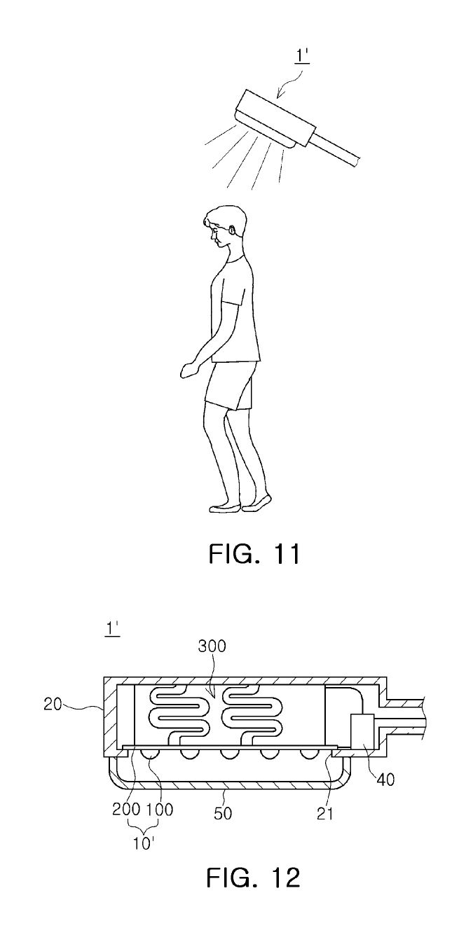

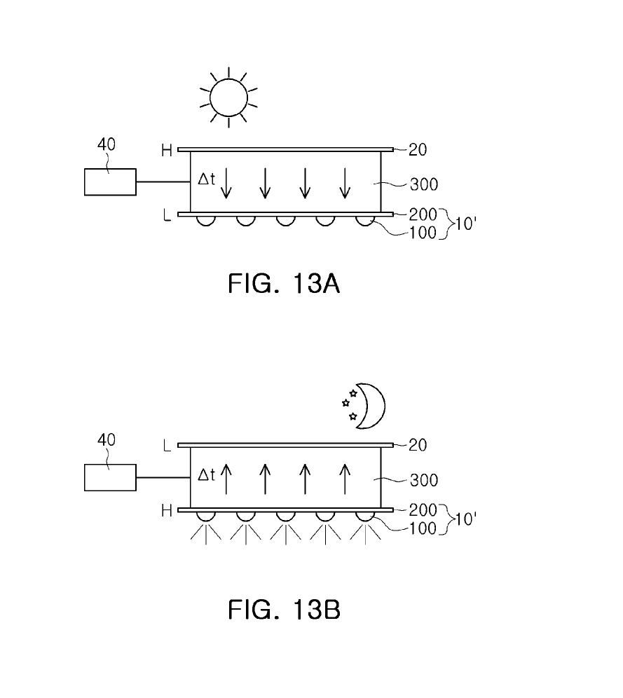

An illumination device according to another embodiment of the present disclosure will be described with reference to FIGS. 11 through 13. FIG. 11 is a view schematically illustrating an illumination device according to another embodiment of the present disclosure. FIG. 12 is a cross-sectional view of the illumination device of FIG. 11. FIGS. 13A and 13B are views schematically illustrating operational states of the illumination device in the daytime and nighttime.

Referring to FIGS. 11 and 12, an illumination device 1′ according to another embodiment of the present disclosure may include the body 20, the light source 10′, the thermoelectric device 300, and the electric condenser 40.

The body 20 is a container type structure having an accommodation space having a predetermined size. The light source 10′, the thermoelectric device 300, the electric condenser 40, or the like, may be installed in the accommodation space of the body 20. The body 20 has the opening 21 to allow light generated by the light source 10′ to be emitted or irradiated therethrough.

The light source 10′ is installed within the body and emits or irradiates light outwardly through the opening 21. The light source 10′ may include at least one light emitting device 100 and the board 200 allowing the light emitting device(s) 100 to be mounted thereon and electrically connecting it.

The thermoelectric device 300 may be installed within the body 20 and generate electricity by using a temperature difference between the body 20 and the light source 10′. A specific structure of the thermoelectric device 300 is illustrated in FIGS. 4 through 8. Since the thermoelectric device 300 has been described in detail with reference to FIGS. 4 through 8, a detailed description thereof will hereinafter be omitted.

As illustrated in FIG. 12, the thermoelectric device 300 may be disposed between the body 20 and the light source 10′ such that one end thereof is connected to the body 20 and the other end thereof is connected to the light source 10′. In this case, the body 20 and the light source 10′ may be a high temperature element H and a low temperature element L (or vice versa), respectively. Namely, in case in that the body 20 corresponds to a high temperature element H, the light source 10′ may correspond to a low temperature element L. Conversely, in case in that the light source 10′ corresponds to a high temperature element H, the body 20 may correspond to a low temperature element L.

The illumination device 1′ according to the present embodiment may be used as a streetlight as illustrated in FIG. 11. In this case, the opening 21 may be disposed in a downward direction to irradiate light toward the ground, and the body 20 opposite the opening 20 may be disposed in an upward direction to face the sun.

As illustrated in FIG. 13A, in most cases, a streetlight is turned off during the day. For example, on a day during which an atmospheric temperature is 30° C., a temperature of an upper portion of the body 20, heated by the warmth of the sun, may be generally increased to approximately 89° C. Since the light source 10′ is in a turned-off state, it may have a temperature similar to the atmospheric temperature. Thus, during the day, the body 20 is a high temperature element H while the light source 10′ is a low temperature element L, and a temperature difference of approximately 60° C. may be generated between the high temperature element H and the low temperature element L. Electricity generated through the temperature difference Δt may be stored in the electric condenser 40.

Meanwhile, as illustrated in FIG. 13, at night, there is no sunlight, and the atmospheric temperature is the lowest of the day. Meanwhile, the light source 10′ is in a turned-on state. Thus, during the night, the body 20 is exposed to the low atmospheric temperature and is thus cooled so as to function as a low temperature element L while the light source 10′ generating thermal energy by the light emission of the light emitting device 100 is a high temperature element H, and a temperature gradient or difference may be generated between the high temperature element H and the low temperature element L. Electricity generated through the temperature difference Δt may be stored in the electric condenser 40.

In the present embodiment, a lamp bulb and a streetlight are illustrated as examples of the illumination device 1 and 1′, but the present disclosure is not limited thereto. For example, teachings described in the present disclosure may be applied to various products using a light emitting device as a light source, such as in a vehicle headlight. Also, since the thermoelectric device 300 is flexible, it may be fabricated in the form of fabric. For example, the present disclosure may be applied to a product such as clothing, besides an illumination device. In this case, electricity may be generated based on a temperature difference between a body temperature and an atmosphere temperature.

The condenser 40 may be connected to the thermoelectric device 300 and the light source 10′ to store electricity generated by the thermoelectric device 300, and to provide the electricity to the light source 10′ as necessary. Thus, power consumption for operating the light source 10′ may be reduced. Also, during the day, thermal energy from sunlight may be used, and during the night, thermal energy generated by operating the light source 10′ may be used to generate electricity and charge a condenser, thus reducing energy consumption.

The body 20 may include a cover 50 (see, e.g., FIGS. 9 and 12) to cover the opening 21 to protect the light source 10′, the thermoelectric device 300, and the like. The cover 50 may be made of a material such as polycarbonate (PC), plastic, silica, acryl, glass, or the like, and may be formed to be transparent or translucent.

The cover 50 may be detachably attached to the body 20. Thus, components such as the light source 10′ or the thermoelectric device 300 installed in the body 20 may be easily replaced.

As set forth above, according to embodiments of the disclosure, the light source module capable of producing electric power at low cost and enhancing energy usage efficiency and the illumination device including the same, relative to the related art, can be provided.

While the present disclosure has been shown and described in connection with certain illustrative embodiments, it will be apparent to those skilled in the art that modifications and variations can be made without departing from the spirit and scope of the disclosure as defined by the appended claims.

What is claimed is:

1. A light source module comprising:
at least one light emitting device; and
a thermoelectric device coupled to the at least one light emitting device and comprising a plurality of conductive layers, made of a resin material containing a thermoelectric conversion material, and a plurality of insulating layers laminated to the conductive layers, the thermoelectric device generating electricity by using heat from the light emitting device.

2. The light source module of claim 1, wherein the thermoelectric conversion material comprises carbon nanotubes (CNT), and the resin material is an organic substance.

3. The light source module of claim 1, wherein the thermoelectric device comprises a first conductive layer including n-type CNT, a second conductive layer including p-type CNT, and an insulating layer in contact with and interposed between the first conductive layer and the second conductive layer.

4. The light source module of claim 3, wherein the thermoelectric device is a film having a multilayer structure formed by alternately laminated conductive layers and insulating layers such that each insulating layer is interposed between a pair of conductive layers, and such that each insulating layer contacts a conductive layer including n-type CNT on one side thereof and contacts a conductive layer including p-type CNT on an other side thereof.

5. The light source module of claim 3, wherein the first conductive layer and the second conductive layer are made of a resin material comprising n-type CNT and p-type CNT respectively, and the first conductive layer and the second conductive layer are formed as thin films.

6. The light source module of claim 3, wherein the first conductive layer and the second conductive layer contact each other to form a junction at one end of the insulating layer.

7. The light source module of claim 4, wherein conductive layers disposed on opposite sides of an insulating layer contact each other to form a junction at one end of the insulating layer, and junctions are formed at alternating ends of the laminated conductive layers in the lamination direction to connect the conductive layers in a zigzag pattern.

8. The light source module of claim 3, wherein the thermoelectric device has ductility so as to be bent or folded.

9. The light source module of claim 3, further comprising:
a housing accommodating and supporting the thermoelectric device therein.

10. An illumination device comprising:
a body having an opening;
a light source installed within the body and emitting light outwardly through the opening; and
a thermoelectric device installed within the body and comprising a plurality of conductive layers, made of a resin material containing carbon nanotubes (CNT), and a plurality of insulating layers laminated to the conductive layers, the thermoelectric device generating electricity by using a temperature difference between the body and the light source.

11. The illumination device of claim 10, wherein the thermoelectric device comprises a first conductive layer including n-type CNT, a second conductive layer including p-type CNT, and an insulating layer in contact with and interposed between the first and second conductive layers.

12. The illumination device of claim 11, wherein the thermoelectric device is a multilayer structure formed by alternately laminated conductive layers and insulating layers such that each insulating layer is interposed between a pair of conductive layers, and such that each insulating layer contacts a conductive layer including n-type CNT on one side thereof and contacts a conductive layer including p-type CNT on an other side thereof.

13. The illumination device of claim 10, wherein the thermoelectric device is disposed between the body and the light source such that one end thereof is connected to the main body and the other end thereof is connected to the light source.

14. The illumination device of claim 10, wherein the body is heated or cooled according to an external environment to form a temperature difference relative to the light source.

15. The illumination device of claim 10, further comprising:
an electric condenser, coupled to the thermoelectric device, for storing electricity generated by the thermoelectric device and providing the stored electricity to the light source.

16. The illumination device of claim 10, further comprising:
a cover installed in the body and covering the light source.

17. A light source module comprising:
a light emitting device; and
a thermoelectric device coupled to the light emitting device and comprising a plurality of conductive layers and a plurality of insulating layers laminated to the conductive layers, the thermoelectric device generating electricity by using heat from the light emitting device,
wherein the thermoelectric device is a multilayer structure including alternately laminated conductive layers and insulating layers such that each insulating layer is interposed between a pair of conductive layers, and
wherein conductive layers disposed on opposite sides of an insulating layer contact each other to form a junction at one end of the insulating layer.

18. The light source module of claim 17, wherein the junctions between conductive layers formed at ends of the insulating layers are formed at alternating ends of the conductive layers in the multilayer structure.

19. The light source module of claim 18, wherein the conductive layers in the multilayer structure alternately include a thermoelectric conversion material including n-type carbon nanotubes (CNTs) and a thermoelectric conversion material including p-type CNTs, such that each junction is formed between a thermoelectric conversion material including n-type CNTs and a thermoelectric conversion material including p-type CNTs.

20. The light source module of claim 17, wherein the thermoelectric device is coupled to the light emitting device by one end surface of the thermoelectric device that contacts a plurality of the conductive layers and a plurality of the insulating layers of the multilayer structure.
